(19) United States
(12) Patent Application Publication
(10) Pub. No.: US 2026/0047154 A1
(43) Pub. Date: Feb. 12, 2026

(54) SILICON CARBIDE SEMICONDUCTOR DEVICE

(71) Applicant: DENSO CORPORATION, Kariya-city (JP)

(72) Inventor: Takuma KATANO, Kariya-city (JP)

(21) Appl. No.: 19/365,584

(22) Filed: Oct. 22, 2025

Related U.S. Application Data
(63) Continuation of application No. PCT/JP2024/016351, filed on Apr. 25, 2024.

(30) Foreign Application Priority Data
Apr. 26, 2023 (JP) 2023-072620

(51) Int. Cl. H10D 62/10; H10D 30/01; H10D 30/66; H10D 62/00; H10D 62/832

(52) U.S. Cl. CPC H10D 62/109; H10D 30/0297; H10D 30/668; H10D 30/669; H10D 62/054; H10D 62/107; H10D 62/127; H10D 62/8325

(57) ABSTRACT

A silicon carbide semiconductor device has a cell region that includes a main cell region, a sense cell region, and an element isolation region electrically separating the main cell region and the sense cell region. The element isolation region includes a plurality of isolation trenches and a plurality of isolation deep layers of a second conductivity type. The isolation trenches are disposed between the main cell region and the sense cell region, and extend deeper than a base layer to separate the base layer into a section adjacent to the main cell region and a section adjacent to the sense cell region. The isolation deep layers are respectively disposed at bottom portions of the isolation trenches in contact with bottom surfaces of the isolation trenches.

### CROSS REFERENCE TO RELATED APPLICATIONS

The present application is a continuation application of International Patent Application No. PCT/JP2024/016351 filed on Apr. 25, 2024, which designated the U.S. and claims the benefit of priority from Japanese Patent Application No. 2023-072620 filed on Apr. 26, 2023. The entire disclosures of all of the above applications are incorporated herein by reference.

### TECHNICAL FIELD

The present disclosure relates to a silicon carbide (hereinafter also referred to as “SiC”) semiconductor device having a main cell region and a sense cell region.

### BACKGROUND

Conventionally, an SiC semiconductor device has been proposed in which a cell region includes a main cell region and a sense cell region, and a current that flows through the main cell region is detected in the sense cell region.

### SUMMARY

A silicon carbide semiconductor device according to an aspect of the present disclosure has a cell region that includes a main cell region, a sense cell region, and an element isolation region electrically separating the main cell region and the sense cell region. The silicon carbide semiconductor device includes a substrate made of silicon carbide of a first conductivity type or a second conductivity type, and a first impurity region of the first conductivity type having a lower impurity concentration than the substrate and disposed above a front surface of the substrate. Both the main cell region and the sense cell region include a junction field effect transistor (JFET) layer made of silicon carbide of the first conductivity type, a deep layer made of silicon carbide of the second conductivity type, a base layer made of silicon carbide of the second conductivity type, a trench gate structure, a second impurity region made of silicon carbide of the first conductivity type, a first electrode separately disposed in the main cell region and the sense cell region, and a second electrode. The JFET layer is disposed in a surface layer of the first impurity region, and has a higher impurity concentration than the first impurity region. The deep layer is disposed in the surface layer of the first impurity region, and is arranged alternately with the JFET layer in a planar direction of the substrate. The base layer is disposed above the JFET layer and the deep layer. The trench gate structure includes a plurality of gate trenches arranged in parallel along one direction as a longitudinal direction and extending deeper than the base layer, a gate insulating film disposed on inner wall surfaces of the gate trenches, and a gate electrode disposed on the gate insulating film within the gate trenches. The second impurity region is disposed in a surface layer of the base layer in contact with the trench gate structure, and has a higher impurity concentration than the first impurity region. The first electrode disposed in the main cell region is electrically connected to the second impurity region and the base layer disposed in the main cell region. The first electrode disposed in the sense cell region is electrically connected to the second impurity region and the base layer disposed in the sense cell region. The second electrode is disposed on a rear surface of the substrate and is electrically connected to the substrate. The element isolation region may include a plurality of isolation trenches and a plurality of isolation deep layers of the second conductivity type. The isolation trenches may be disposed between the main cell region and the sense cell region, and may extend deeper than the base layer to separate the base layer into a section adjacent to the main cell region and a section adjacent to the sense cell region. The isolation deep layers may be respectively disposed at bottom portions of the isolation trenches in contact with bottom surfaces of the isolation trenches.

### BRIEF DESCRIPTION OF DRAWINGS

Objects, features and advantages of the present disclosure will become apparent from the following detailed description made with reference to the accompanying drawings. In the drawings:

FIG. 1 is a plan view of an SiC semiconductor device according to a first embodiment;

FIG. 2 is a perspective cross-sectional view of region RA in FIG. 1 as seen from direction shown by arrow II;

FIG. 3 is a cross-sectional view of the SiC semiconductor device taken along line III-III in FIG. 1;

FIG. 4 is a cross-sectional view of the SiC semiconductor device taken along line IV-IV in FIG. 1;

FIG. 5 is a cross-sectional view of the SiC semiconductor device taken along line V-V in FIG. 1;

FIG. 6A is a cross-sectional view showing a manufacturing process of the SiC semiconductor device according to the first embodiment;

FIG. 6B is a cross-sectional view showing a manufacturing process following FIG. 6A;

FIG. 6C is a cross-sectional view showing a manufacturing process following FIG. 6B;

FIG. 6D is a cross-sectional view showing a manufacturing process following FIG. 6C; and

FIG. 6E is a cross-sectional view showing a manufacturing process following FIG. 6D.

### DETAILED DESCRIPTION

Next, an SiC semiconductor device according to a related art will be described to facilitate understanding of the following embodiments. The SiC semiconductor device according to the related art has a cell region including a main cell region and a sense cell region, and is configured such that a current that flows through the main cell region is detected in the sense cell region. In this SiC semiconductor device, metal oxide semiconductor field effector transistor (MOSFET) elements having the same structure are formed in both the main cell region and the sense cell region. In addition, in this SiC semiconductor device, an element isolation region is disposed between the main cell region and the sense cell region so that element isolation between the main cell region and the sense cell region is achieved.

Both the main cell region and the sense cell region have a trench gate structure. A protective layer of p-type is formed at a bottom of a trench in the trench gate structure, so that a depletion layer is extended from the protective layer to a drift layer, and an electric field applied to the bottom of the trench is alleviated.

In the element isolation region, a single wide trench reaching down to the drift layer is formed between the main cell region and the sense cell region, and protective layers of p-type that constitute electric field relief layers are formed at both ends of a bottom portion of this trench, that is, an end of the bottom portion adjacent to the main cell and an end of the bottom portion adjacent to the sense cell. In this way, by providing the electric field relief layers at both ends of the single wide trench, high breakdown voltage is achieved, while the electric field relief layer adjacent to the main cell region and the electric field relief layer adjacent to the sense cell region are separated by a dividing portion, thereby preventing the main cell region and the sense cell region from being short-circuited through the electric field relief layers.

In a manufacturing method of the SiC semiconductor device described above, a resist mask used for forming the trench of the MOSFET is positioned at the central location of the wide trench, and the electric field relief layers may be uniformly provided at the bottom portion of the trench except for an area covered by the resist mask. However, in such a case where the electric field relief layers are provided in this manner, the processing of the mask becomes unstable, and the electric field relief layers may become connected, making it impossible to isolate the main cell region and the sense cell region.

A silicon carbide semiconductor device according to an aspect of the present disclosure has a cell region that includes a main cell region, a sense cell region, and an element isolation region electrically separating the main cell region and the sense cell region. The silicon carbide semiconductor device includes a substrate made of silicon carbide of a first conductivity type or a second conductivity type, and a first impurity region of the first conductivity type having a lower impurity concentration than the substrate and disposed above a front surface of the substrate. Both the main cell region and the sense cell region include a JFET layer made of silicon carbide of the first conductivity type, a deep layer made of silicon carbide of the second conductivity type, a base layer made of silicon carbide of the second conductivity type, a trench gate structure, a second impurity region made of silicon carbide of the first conductivity type, a first electrode separately disposed in the main cell region and the sense cell region, and a second electrode. The JFET layer is disposed in a surface layer of the first impurity region, and has a higher impurity concentration than the first impurity region. The deep layer is disposed in the surface layer of the first impurity region, and is arranged alternately with the JFET layer in a planar direction of the substrate. The base layer is disposed above the JFET layer and the deep layer. The trench gate structure includes a plurality of gate trenches arranged in parallel along one direction as a longitudinal direction and extending deeper than the base layer, a gate insulating film disposed on inner wall surfaces of the gate trenches, and a gate electrode disposed on the gate insulating film within the gate trenches. The second impurity region is disposed in a surface layer of the base layer in contact with the trench gate structure, and has a higher impurity concentration than the first impurity region. The first electrode disposed in the main cell region is electrically connected to the second impurity region and the base layer disposed in the main cell region. The first electrode disposed in the sense cell region is electrically connected to the second impurity region and the base layer disposed in the sense cell region. The second electrode is disposed on a rear surface of the substrate and is electrically connected to the substrate. The element isolation region includes a plurality of isolation trenches and a plurality of isolation deep layers of the second conductivity type. The isolation trenches are disposed between the main cell region and the sense cell region, and extend deeper than the base layer to separate the base layer into a section adjacent to the main cell region and a section adjacent to the sense cell region. The isolation deep layers are respectively disposed at bottom portions of the isolation trenches in contact with bottom surfaces of the isolation trenches.

In this manner, the isolation trenches are formed in the element isolation region to separate the base layer into the section adjacent to the main cell region and the section adjacent to the sense cell region. As a result, the section of the base layer located adjacent to the main cell region and the section of the base layer adjacent located adjacent to the sense cell region can be electrically separated. In addition, by providing the isolation deep layers, the rise of equipotential lines between the main cell region and the sense cell region can be suppressed, thereby ensuring breakdown voltage. Furthermore, since the plurality of isolation trenches are provided, there is no need to make each of the isolation trenches as wide as in the case of providing a single isolation trench. As a result, the formation quality of the isolation trenches and the isolation deep layers formed at their bottoms is improved, and each of the isolation deep layers can be accurately formed with appropriate spacing therebetween. Therefore, it is possible to suppress source leakage caused by the isolation deep layer located adjacent to the main cell region and the isolation deep layer located adjacent to the sense cell region being connected and short-circuited. Accordingly, the SiC semiconductor device can ensure a high breakdown voltage in the element isolation region while accurately achieving element isolation between the main cell region and the sense cell region.

Hereinafter, embodiments of the present disclosure will be described with reference to the drawings. In the following embodiments, the same or equivalent parts are designated with the same reference numerals.

### First Embodiment

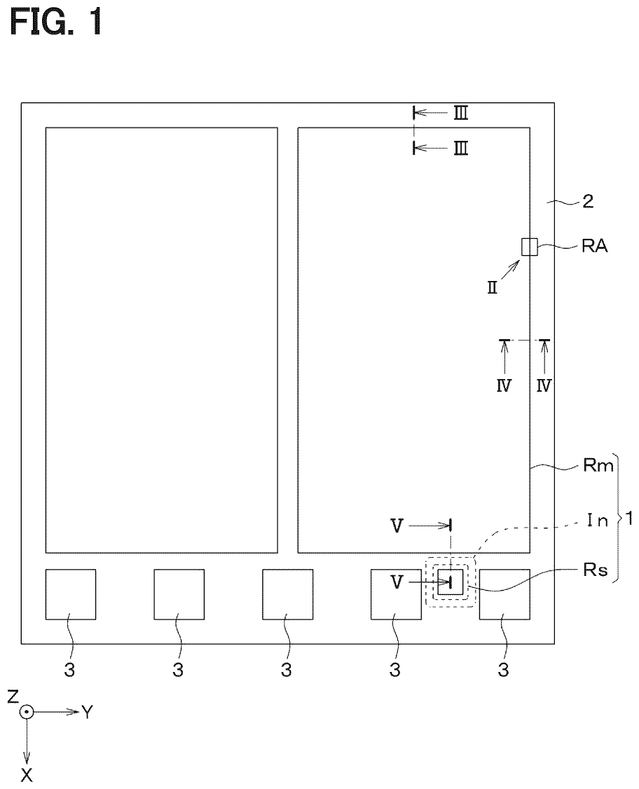

A first embodiment will be described with reference to the drawings. The SiC semiconductor device of the present embodiment is configured, as shown in FIG. 1, to include a cell region 1, which serve as an active region where device operation occurs, and a peripheral region 2 that surrounds the cell region 1. The cell region 1 includes a main cell region Rm including main cells, a sense cell region Rs including sense cells, and an element isolation region In disposed between the main cell region Rm and the sense cell region Rs, and electrically isolating the main cell region Rm and the sense cell region Rs. In the present embodiment, the SiC semiconductor device is configured such that a main current that flows through the main cell region Rm can be detected based on a sense current that flows through the sense cell region Rs and an area ratio.

Below the cell region 1 in FIG. 1, various pads 3 are disposed for purposes such as controlling the elements provided in the cell region 1 and detecting temperature.

In the present embodiment, the sense cell region Rs is arranged adjacent to the main cell region Rm. The element isolation region In is arranged in the shape of a frame so as to surround the sense cell region Rs. In the main cell region Rm and the sense cell region Rs, semiconductor elements having the same trench gate structure are disposed.

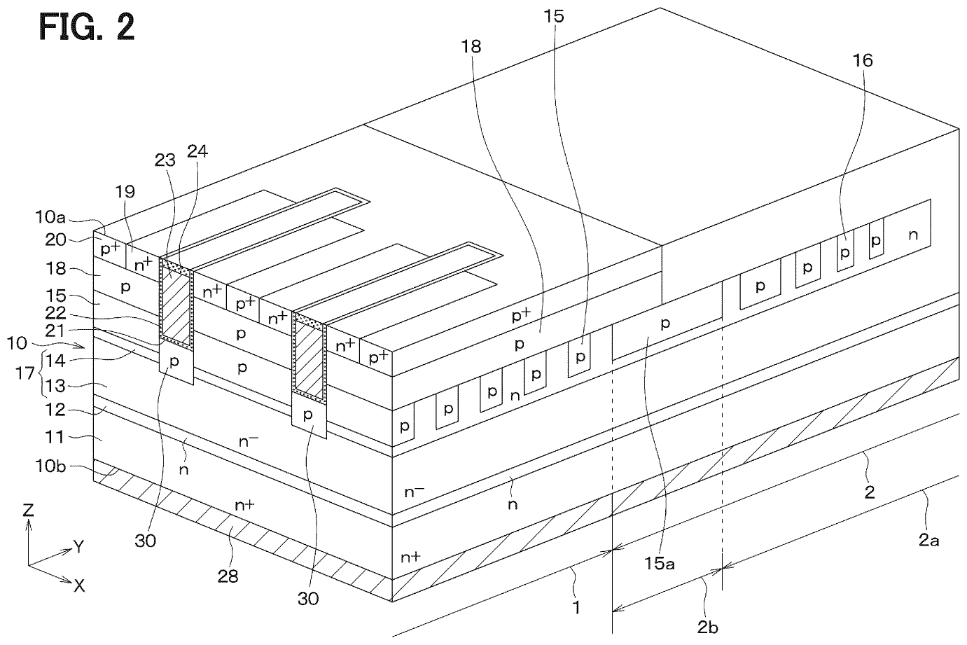

As shown in FIG. 2, the peripheral region 2 is configured to include a guard ring section 2a and a connecting section 2b. The guard ring section 2a has a peripheral breakdown voltage structure. The connecting section 2b is disposed on an inner side of the guard ring section 2a. In other words, the peripheral region 2 is configured to include the guard ring section 2a and the connecting section 2b, and the connecting section 2b is disposed between the cell region 1 and the guard ring section 2a.

Hereinafter, an SiC semiconductor device in which a vertical n-channel MOSFET as a semiconductor element having a trench gate structure is disposed in the cell region 1 will be described with reference to FIGS. 2 to 5. As described above, vertical MOSFETs having the same structure are disposed in the main cell region Rm and the sense cell region Rs. In the following description, one direction in a planar direction of the semiconductor substrate 10, which will be described later, is referred to as an X-axis direction, a direction intersecting the X-axis direction in the planar direction of the semiconductor substrate 10 is referred to as a Y-axis direction, and a direction intersecting both the X-axis and Y-axis directions is referred to as a Z-axis direction. In the present embodiment, the X-axis, Y-axis, and Z-axis directions are defined as mutually orthogonal axes. Additionally, in the present embodiment, the Z-axis direction corresponds to a thickness direction of the semiconductor substrate 10, which will be described later, and also corresponds to a laminating direction of the substrate 11 and a low-concentration layer 13, which will also be described later. The Y-axis direction is, for example, the <11-20> direction.

The SiC semiconductor device is configured using the semiconductor substrate 10 on which the vertical MOSFET elements are disposed. The semiconductor substrate 10 is formed by forming various semiconductor layers made of SiC on a substrate 11 of n⁺-type composed of SiC. In the present embodiment, the substrate 11 has an off-angle of 0 to 8 degrees with respect to, for example, a (0001) Si plane. The substrate 11 has an n-type impurity, such as nitrogen or phosphorus, at a concentration of 1.0×10¹⁹/cm³, and has a thickness of about 300 μm. In the case of the vertical MOSFETs, the substrate 11 constitutes the drain regions.

On a surface of the substrate 11, a buffer layer 12 made of SiC of n-type may be disposed as needed. The buffer layer 12 is formed by epitaxial growth on the surface of the substrate 11. The buffer layer 12 has an n-type impurity concentration set between the n-type impurity concentration of the substrate 11 and an n-type impurity concentration of the low-concentration layer 13 described later. The buffer layer 12 has a thickness of about 1 μm.

On a surface of the buffer layer 12, for example, the low-concentration layer 13 made of SiC of n-type is disposed. The low-concentration layer 13 has an n-type impurity concentration of 5.0×10¹⁵ to 2.0×10¹⁶/cm³ and has a thickness of about 7 to 15 μm. The low-concentration layer 13 may have a constant impurity concentration along the Z-axis direction. However, the concentration distribution may be inclined so that the concentration of a portion of the low-concentration layer 13 closer to the substrate 11 is higher than the concentration of the other portion farther from the substrate 11. In the present embodiment, the low-concentration layer 13 corresponds to a first impurity region.

In a surface layer of the low-concentration layer 13 in the cell region 1, a junction field effect transistor (JFET) layer 14 and first deep layers 15 are disposed. In the present embodiment, the JFET layer 14 and the first deep layers 15 extend along the X-axis direction and have linear portions that are alternately and repeatedly arranged along the Y-axis direction. That is, the JFET layer 14 and the first deep layers 15 are formed in a stripe shape extending along the X-axis direction in the normal direction to the surface of the substrate 11 (hereinafter simply referred to as the normal direction), and are arranged in a layout in which the JFET layer 14 and the first deep layer 15 are alternately arranged in the Y-axis direction. Here, “in the normal direction to the surface of the substrate 11” means as viewed from a direction perpendicular to the surface of the substrate 11. In addition, the normal direction to the surface of the substrate 11 is also the direction along which a drift layer 17 and a base layer 18, described later, are laminated, that is, the direction along the Z-axis.

The JFET layer 14 is of n-type with a higher impurity concentration than the low-concentration layer 13, and has a thickness of 0.3 to 1.5 μm. In the present embodiment, the JFET layer 14 has an n-type impurity concentration of about 5.0×10¹⁶ to 1.0×10¹⁷/cm³. The first deep layers 15 have a p-type impurity concentration of about 2.0×10¹⁷ to 2.0×10¹⁸/cm³. It should be noted that, in the present embodiment, the JFET layer 14 is not disposed in the element isolation region In of the cell region 1. In other words, in the cell region 1, the JFET layer 14 is disposed only in the main cell region Rm and the sense cell region Rs. In the present embodiment, a region within the cell region 1 where the JFET layer 14 is not disposed is designated as the element isolation region In.

The first deep layers 15 may be formed to a depth equal to that of the JFET layer 14, or deeper or shallower than the JFET layer 14. In the present embodiment, the first deep layers 15 are formed shallower than the JFET layer 14. In other words, the first deep layers 15 are formed such that bottom portions of the first deep layers 15 are positioned within the JFET layer 14. In other words, the first deep layers 15 are formed such that the JFET layer 14 is positioned between the first deep layers 15 and the low-concentration layer 13. As a result, the expansion of the depletion layer into the JFET layer 14 between the first deep layers 15 is suppressed, thereby reducing the on-resistance. The JFET layer 14 and the first deep layers 15 are formed by appropriately implanting impurities into the surface layer of the low-concentration layer 13.

Meanwhile, in the guard ring section 2a of the peripheral region 2, the JFET layer 14 extends in the surface layer of the low-concentration layer 13. Within the JFET layer 14, p-type guard rings 16 are disposed so as to surround the cell region 1. In the present embodiment, a top layout of the guard rings 16 is set in a shape such as a rectangle with rounded corners or a circular shape when viewed in the normal direction.

Furthermore, in the connecting section 2b of the peripheral region 2, a connecting layer 15a of p-type is disposed in the surface layer of the low-concentration layer 13. The connecting layer 15a is arranged such that the inner edge of the connecting layer 15a surrounds the cell region 1, and the outer edge of the connecting layer 15a extends to a boundary position with the guard ring section 2a. The connecting layer 15a is formed by extending the first deep layers 15 to the connecting section 2b, and has the same depth and the same p-type impurity concentration as the first deep layers 15.

In addition, the base layer 18, a source region 19, a contact region 20, and the like are disposed above the JFET layer 14 and the first deep layers 15 in the cell region 1.

The base layer 18 is of p-type and is disposed on the JFET layer 14 and the first deep layers 15. Therefore, the first deep layers 15 are in a state of being connected to the base layer 18. The base layer 18, for example, has a p-type impurity concentration of 5.0×10¹⁶ to 2.0×10¹⁹/cm³ and a thickness of about 2.0 μm.

The source region 19 is of n⁺-type and is disposed in a surface layer of the base layer 18. The contact region 20 is of p⁺-type and is disposed in the surface layer of the base layer 18. Specifically, the source region 19 is formed so as to be in contact with a sidewall of a trench 21, which will be described later, and the contact region 20 is formed on the opposite side of the source region 19 from the trench 21. In the present embodiment, the source region 19 has an n-type impurity concentration in a surface layer, that is, a surface concentration of, for example, 1.0×10¹⁸/cm³, and has a thickness of about 0.3 μm. The contact region 20 has a p-type impurity concentration in a surface layer, that is, a surface concentration of, for example, 1.0×10²¹/cm³, and has a thickness of about 0.3 μm. In the present embodiment, the source region 19 corresponds to a second impurity region.

Above the low-concentration layer 13, the JFET layer 14, the first deep layers 15, and the connecting layer 15a in the connecting section 2b of the peripheral region 2, the base layer 18, the contact region 20, and the surface layer of the low-concentration layer 13, and the like are formed. At the inner edge of the connecting section 2b, the base layer 18 and the contact region 20 are formed above the connecting layer 15a and extend from the cell region 1. At the outer edge of the connecting section 2b, the base layer 18 and the contact region 20 are not formed, and the surface layer of the low-concentration layer 13 is formed. That is, in the present embodiment, the base layer 18 and the contact region 20 in the peripheral region 2 are formed so as to extend from the cell region 1 and are formed up to an intermediate portion of the connecting section 2b, but are not formed in a portion of the connecting section 2b outside the intermediate portion, nor in the guard ring portion 2a. Then, from the boundary position between the cell region 1 and the peripheral region 2 to the intermediate portion of the connecting section 2b, the entire surface layer of the connecting section 2b is provided by the contact region 20. Beyond the intermediate portion, the entire surface layer of the connecting section 2b and the guard ring portion 2a is provided by the low-concentration layer 13.

In the present embodiment, as described above, the semiconductor substrate 10 is configured to include the substrate 11, the buffer layer 12, the low-concentration layer 13, the JFET layer 14, the first deep layers 15, the base layer 18, the source region 19, the contact region 20, and the like. Since each layer constituting the semiconductor substrate 10 is made of SiC, it can be said that the semiconductor substrate 10 is made of SiC. In the present embodiment, in the cell region 1 and the inner edge of the connecting section 2b, front surface 10a of the semiconductor substrate 10 is constituted by the source region 19, the contact region 20, and the like, while a rear surface 10b of the semiconductor substrate 10 is constituted by the substrate 11.

It should be noted that, in the present embodiment, the JFET layer 14, the first deep layers 15, the connecting layer 15a, the guard rings 16, the base layer 18, the source region 19, and the contact region 20 are constituted as ion-implanted layers formed by ion implantation.

In addition, in the cell region 1, trenches 21 are formed in the semiconductor substrate 10 so as to penetrate through the source region 19, the base layer 18, and the like, reaching the JFET layer 14 and the first deep layers 15 from the front surface 10a. The trenches 21 correspond to gate trenches. The trenches 21 have a depth such that their bottom surfaces are located within the JFET layer 14 and the first deep layers 15, and have a width of, for example, 0.4 to 0.8 μm.

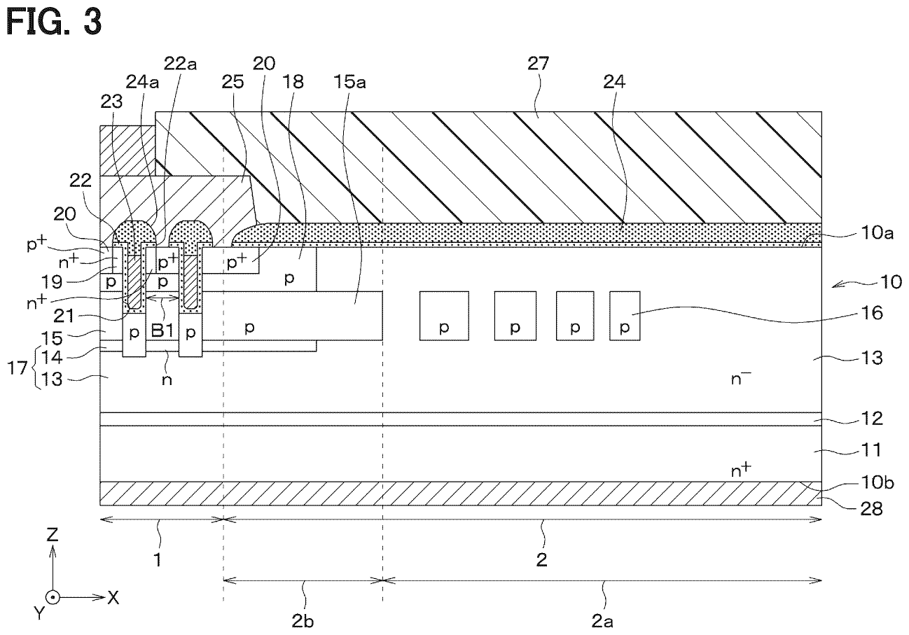

In addition, the trenches 21 extend along the Y-axis direction. As shown in FIG. 3, the trenches 21 are arranged in a stripe pattern at equal intervals with a spacing of B1 in the X-axis direction. That is, in the present embodiment, the trenches 21 are formed such that their longitudinal direction is orthogonal to the longitudinal direction of the first deep layers 15.

At the bottom portions of the trenches 21, second deep layers 30 serving as electric field relief layers are respectively disposed so as to be in contact with bottom surfaces of the trenches 21. In the present embodiment, the second deep layers 30 are constituted by p-type layers having a lower impurity concentration than the first deep layers 15. Specifically, the second deep layers 30 are formed along the longitudinal direction of the trenches 21. That is, the second deep layers 30 extend along the Y-axis direction, which intersects the first deep layers 15. Furthermore, in the present embodiment, the second deep layers 30 are formed so as to penetrate through the JFET layer 14 and the first deep layers 15, with their bottom surfaces reaching the low-concentration layer 13.

By forming the second deep layers 30 along the bottom surfaces of the trenches 21, it is possible to suppress the penetration of the electric field into the gate insulating films 22 located at the bottoms of the trenches 21, thereby preventing oxide film breakdown. In addition, by forming the second deep layers 30 so as to be in contact with the bottom surfaces of the trenches 21, a capacitance between gate electrodes 23 and a lower electrode 28, namely a feedback capacitance, can be reduced, thereby improving the switching speed. Furthermore, since the second deep layers 30 are formed so as to penetrate through the JFET layer 14 and the first deep layers 15, with their bottom surfaces reaching the low-concentration layer 13, the creeping up of the electric field into the JFET layer 14 located between the second deep layers 30 can be suppressed, thereby improving the breakdown voltage. In addition, when an overvoltage is applied, breakdown is more likely to occur in the second deep layers 30, which protrude downward, making it easier for breakdown to occur in the cell region 1 and thereby improving avalanche tolerance.

It should be noted that the second deep layers 30 may be formed as a plurality of segments separated in the Y-axis direction. However, the second deep layers 30 are formed so as to be electrically connected to the base layer 18 via the first deep layers 15.

In addition, in each of the trenches 21, a gate insulating film 22 is formed on an inner wall surface, and a gate electrode 23, which is made of doped polycrystalline silicon or the like, is formed on the gate insulating film 22. Accordingly, the trench gate structure is formed. The method of forming the gate insulating film 22 is not particularly limited, but the gate insulating film 22 may be formed by thermally oxidizing the inner wall surface of each of the trenches 21 or by depositing an insulating film using a chemical vapor deposition (CVD) method. The gate insulating film 22 has a thickness of about 100 nm on both the sidewall and the bottom surface of each of the trenches 21.

The gate insulating film 22 is formed not only on the inner wall surface of each of the trenches 21, but also on the front surface 10a of the semiconductor substrate 10. Then, in the cell region 1, the gate insulating film 22 has contact holes 22a exposing the source region 19 and the contact region 20 therethrough.

On the front surface 10a of the semiconductor substrate 10, an interlayer insulating film 24 is disposed so as to cover the gate electrode 23, the gate insulating film 22, and the like. The interlayer insulating film 24 is made of borophosphosilicate glass (BPSG) or the like. It should be noted that in FIG. 2, the interlayer insulating film 24 and the like, which are located above the front surface 10a of the semiconductor substrate 10, are omitted.

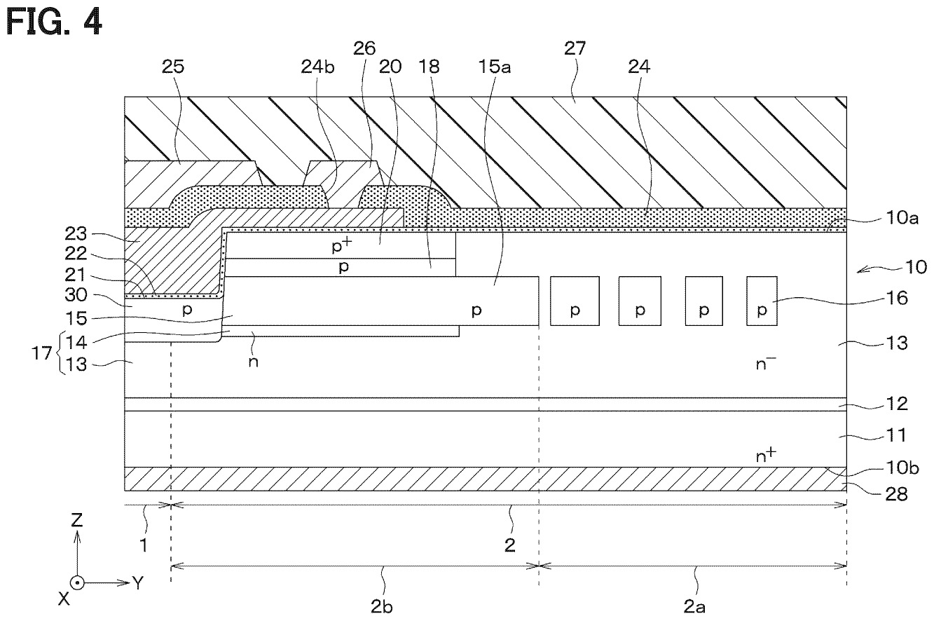

As shown in FIG. 3, in the cell region 1, the interlayer insulating film 24 has contact holes 24a communicating with the contact holes 22a and exposing the source region 19 and the contact region 20. Furthermore, as shown in FIG. 4, the interlayer insulating film 24 has contact holes 24b exposing a portion of the gate electrode 23 that extends to the connecting section 2b.

Above the interlayer insulating film 24, an upper electrode 25 is disposed. The upper electrode 25 is electrically connected to the source region 19 and the contact region 20 through the contact holes 22a and 24a. The upper electrode 25 is disposed separately for each of the main cell region Rm and the sense cell region Rs. The upper electrode 25 in the main cell region Rm and the upper electrode 25 in the sense cell region Rs are configured so as to be electrically connected to the outside independently. In the present embodiment, the upper electrode 25 correspond to a first electrode. Furthermore, above the interlayer insulating film 24, a gate wiring 26 is disposed. The gate wiring 26 is electrically connected to the gate electrode 23 through the contact hole 24b. Although not shown in FIG. 1, the gate wiring 26 is formed along an outer edge portion of the cell region 1. For example, in the SiC semiconductor device having a rectangular chip shape shown in FIG. 1, the gate wiring 26 is formed along the right, left, and lower sides of the chip.

The upper electrode 25 of the present embodiment is made of a plurality of metals, such as Ni and Al, for example. Among the plurality of metals, a portion that is in contact with n-type SiC, that is, a portion in contact with a region forming the source region 19, is made of a metal capable of forming an ohmic contact with the n-type SiC. In addition, among the multiple metals, at least a portion that is in contact p-type SiC, that is, a portion in contact with the contact region 20, is made of a metal capable of forming an ohmic contact with the p-type SiC. It should be noted that the gate wiring 26 may have the same structure as the upper electrode 25, or may be made of materials such as Al—Si.

Furthermore, a protective film 27 made of polyimide or the like is disposed so as to cover the connecting section 2b and the guard ring section 2a. In the present embodiment, the protective film 27 is disposed from the peripheral region 2 to the outer edge of the cell region 1 in order to suppress surface discharge between the upper electrode 25 and the lower electrode 28, which will be described later. Specifically, in the cell region 1, the protective film 27 is formed so as to cover a portion of the upper electrode 25 adjacent to the peripheral region 2, while exposing a portion of the upper electrode 25 on the inner edge side.

On the rear surface 10b of the semiconductor substrate 10, the lower electrode 28 electrically connected to the substrate 11 is disposed. It should be noted that, in the present embodiment, the lower electrode 28 corresponds to a second electrode.

In the SiC semiconductor device of the present embodiment, with the above-described structure, trench gate MOSFETs of the n-channel inversion type are formed in both the main cell region Rm and the sense cell region Rs. Next, the configuration of the element isolation region In will be described.

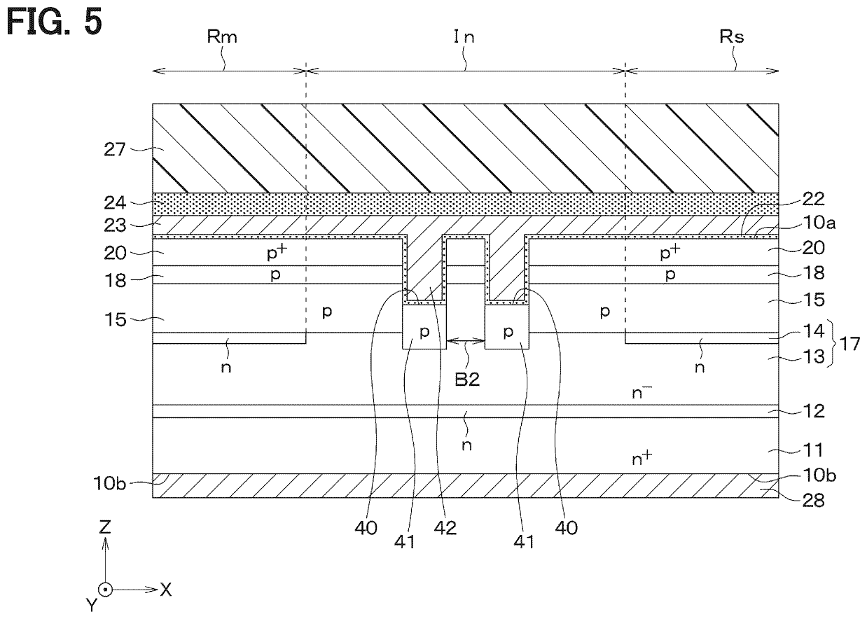

As indicated by the broken line in FIG. 1, the element isolation region In is disposed so as to surround the sense cell region Rs, and is disposed between the main cell region Rm and the sense cell region Rs. Then, as shown in FIG. 5, the element isolation region In includes the substrate 11, the buffer layer 12, and the low-concentration layer 13, similarly to the cell region 1.

In the element isolation region In, the first deep layers 15 are disposed in the surface layer of the low-concentration layer 13, but the JFET layer 14 is not disposed. In other words, within the cell region 1, a region where the JFET layer 14 is not disposed between the main cell region Rm and the sense cell region Rs constitutes the element isolation region In.

Furthermore, the first deep layer 15 located adjacent to the main cell region Rm and the first deep layer 15 located adjacent to the sense cell region Rs are arranged with a gap therebetween, and are separated at a position between the main cell region Rm and the sense cell region Rs. The base layer 18 and the contact region 20 are also disposed above the first deep layers 15. The base layer 18 is disposed in contact with the first deep layer 15. Furthermore, the contact region 20 is formed in the surface layer of the base layer 18. Sections of the base layer 18 and the contact region 20 located adjacent to the main cell region Rm and sections of the base layer 18 and the contact region 20 located adjacent to the sense cell region Rs are also arranged with a gap therebetween, and are separated at positions between the main cell region Rm and the sense cell region Rs.

It should be noted that each component in the element isolation region In has an impurity concentration similar to that of the cell region 1.

Further, in the element isolation region In, a plurality of isolation trenches 40 serving as an isolation structure are formed so as to reach the first deep layers 15. In the present embodiment, two isolation trenches 40 are provided, and each of the isolation trenches 40 is formed so as to surround the sense cell region Rs. The isolation trenches 40 are formed with the same depth and the same width. The isolation trenches 40 are arranged with a spacing B2 therebetween, such that the isolation trenches 40 are separated and not connected to each other. The spacing B2 is set to be equal to or less than the spacing B1 between the adjacent trenches 21 formed in the cell region 1. Furthermore, at the bottom portions of the isolation trenches 40, isolation deep layers 41 are respectively disposed so as to be in contact with bottom surfaces of the isolation trenches 40. The isolation deep layers 41 are formed over the entire area of the bottom portions of the isolation trenches 40. The isolation deep layers 41 only need to be separated at a position between the main cell region Rm and the sense cell region Rs, and they may protrude outward from the bottom surfaces of the isolation trenches 40.

The isolation trenches 40 and the isolation deep layers 41 formed in the element isolation region In have the same structure as the trenches 21 and the second deep layers 30 formed in the cell region 1. That is, the isolation trenches 40 are formed with the same depth and the same width as the trenches 21. The isolation deep layers 41 have the same p-type impurity concentration and the same depth as the second deep layers 30. In addition, the isolation trenches 40 can be formed at the same time as the trenches 21, and the isolation deep layers 41 can be formed at the same time as the second deep layers 30. By unifying the formation processes of the isolation trenches 40 and the isolation deep layers 41 with those of the trenches 21 and the second deep layers 30, the manufacturing process can be simplified.

It is not necessary for the width and depth of all of the isolation trenches 40 to be equal to each other. In addition, it is not necessary for the width and depth of the isolation trenches 40 to be equal to those of the trenches 21. However, when the isolation trenches 40 are formed simultaneously with the trenches 21, if the width of the isolation trenches 40 is made large, for example, larger than the combined width of two trenches 21, variations may occur in the quality of formation of the trenches 21 and the isolation trenches 40. In addition, variations may also occur in the shape and quality of the gate insulating film 22 formed on surfaces of the isolation trenches 40, compared to that formed on the surfaces of the trenches 21 in the cell region 1, which can affect the yield. Therefore, it is preferable that the width of each of the isolation trenches 40 is equal to the width of each of the trenches 21. Furthermore, when the width of each of the isolation trenches 40 is equal to the width of the each of the trenches 21, it also becomes easier to adjust the breakdown voltage and current capacity balance between the cell region 1 and the element isolation region In. It should be noted that, “the width of each of the isolation trenches 40 is equal to the width of the each of the trenches 21” preferably means that the widths are the same, but refers to manufacturing with the intention of making them the same width, and minor manufacturing tolerances are acceptable.

Furthermore, the gate insulating film 22 is formed on the surface of the semiconductor substrate 10 in the element isolation region In, including the inside of the isolation trenches 40. In addition, an isolation gate electrode 42 is formed on the gate insulating film 22. In the present embodiment, the isolation gate electrode 42 is electrically connected to the gate electrode 23. However, the isolation gate electrode 42 may also be separated from the gate electrode 23. When the isolation gate electrode 42 is electrically separated from the gate electrode 23, the gate voltage is not applied to the isolation gate electrode 42 during device operation, thereby improving the breakdown voltage. Then, the interlayer insulating film 24 and the protective film 27 are disposed so as to cover the isolation gate electrode 42. With the above-described structure, the element isolation region In is formed.

In this manner, by providing the isolation trenches 40 and the isolation deep layers 41, the sections of the base layer 18 and the contact region 20 located adjacent to the main cell region Rm are electrically separated from the sections of the base layer 18 and the contact region 20 located adjacent to the sense cell region Rs. Additionally, by providing the isolation deep layers 41, the rise of equipotential lines between the main cell region Rm and the sense cell region Rs can be suppressed, thereby ensuring a high breakdown voltage.

The configuration of the SiC semiconductor device according to the present embodiment is described above. In the present embodiment, the n⁻ type, n type, and n⁺ type correspond to a first conductivity type, while the p type and p⁺ type correspond to a second conductivity type. Next, the operation of the SiC semiconductor device will be described.

First, in the above-described SiC semiconductor device, in the off state before a gate voltage is applied to the gate electrode 23, an inversion layer is not formed in the base layer 18. Therefore, even if a positive voltage, for example 1600 V, is applied to the lower electrode 28, electrons do not flow from the source region 19 into the base layer 18, and no current flows between the upper electrode 25 and the lower electrode 28.

In addition, in a state before a gate voltage is applied to the gate electrode 23, an electric field is applied between the drain and the gate, and an electric field concentration may occur at the bottom of the gate insulating film 22. However, in the above-described SiC semiconductor device, the first deep layers 15 and the JFET layer 14 are disposed at positions deeper than the trenches 21. Therefore, the depletion layer formed between the first deep layers 15 and the JFET layer 14 suppresses the rise of equipotential lines caused by the drain voltage, making it difficult for a high electric field to penetrate into the gate insulating film 22. Furthermore, since the second deep layers 30 serving as the electric field relief layers are disposed at the bottom portions of the trenches 21, it becomes even more difficult for a higher electric field to penetrate into the gate insulating film 22. Therefore, in the present embodiment, breakdown of the gate insulating film 22 can be inhibited.

Additionally, when a predetermined gate voltage is applied to the gate electrode 23, a channel is formed on the surface of the base layer 18 that is in contact with the trenches 21. Therefore, electrons injected from the upper electrode 25 pass through the channel formed in the base layer 18 from the source region 19, then pass through the JFET layer 14 and flow into the low-concentration layer 13, and subsequently pass through the substrate 11 serving as the drain layer to flow to the lower electrode 28. As a result, a current flows between the upper electrode 25 and the lower electrode 28, and the SiC semiconductor device is turned on. In the present embodiment, since the electrons that have passed through the channel flow to the substrate 11 via the JFET layer 14 and the low-concentration layer 13, it can be said that the drift layer 17 is constituted by the JFET layer 14 and the low-concentration layer 13.

Then, in the element isolation region In, while electrically isolating the sections of the base layer 18 and the contact region 20 located adjacent to the main cell region Rm and the sections of the base layer 18 and the contact region 20 located adjacent to the sense cell region Rs by the isolation trenches 40, the isolation deep layers 41 are disposed at the bottom portions of the isolation trenches 40. Therefore, even in the element isolation region In, the rise of equipotential lines due to the influence of the drain voltage is suppressed.

Furthermore, since the spacing B2 between the isolation trenches 40 is set to be equal to or less than the spacing B1 between the trenches 21 formed in the cell region 1, the breakdown voltage in the element isolation region In can be made higher than that in the cell region 1. As a result, it is possible to prevent the element isolation region In, which tends to have a smaller area, from breaking down first. Accordingly, the breakdown voltage of the SiC semiconductor device is limited by the breakdown voltage of the cell region 1, making it possible to design the breakdown voltage of the SiC semiconductor device based on the breakdown voltage design of the cell region 1.

The present inventors have investigated the breakdown voltage between the drain and source. Specifically, at a temperature of 25° C., both the source voltages of the main cell region Rm and the sense cell region Rs were set to 0 V, and the gate voltage was set to-3.5 V. The breakdown voltage was investigated based on simulation analysis by varying the spacing B2. As a result, when the spacing B2 was equal to or less than the spacing B1 of the trenches 21 in the cell region 1, a high breakdown voltage of 1400 V or more was obtained in all cases. In addition, when a similar analysis was conducted at a temperature of 175° C., a high breakdown voltage of 1400 V or more was also obtained. Furthermore, simulation analysis was used to investigate source leakage between the main cell region Rm and the sense cell region Rs. Since the isolation deep layers 41 are separated between the main cell region Rm and the sense cell region Rs, source leakage due to short-circuiting was suppressed.

It should be noted that the width of the element isolation region In is not limited, as long as the width is within a range that ensures breakdown voltage and suppresses source leakage. However, the element isolation region In becomes an inactive region in which current is difficult to flow. Therefore, it is preferable that the width of the element isolation region In be made as narrow as possible, while taking into consideration the breakdown voltage and source leakage. Based on this, the spacing B1, the width, and the number of the isolation trenches 40 may be set accordingly.

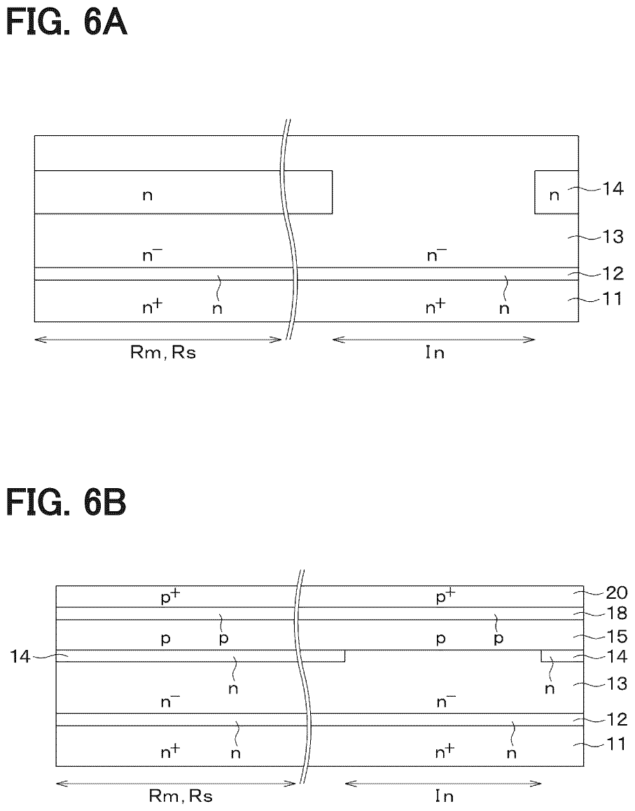

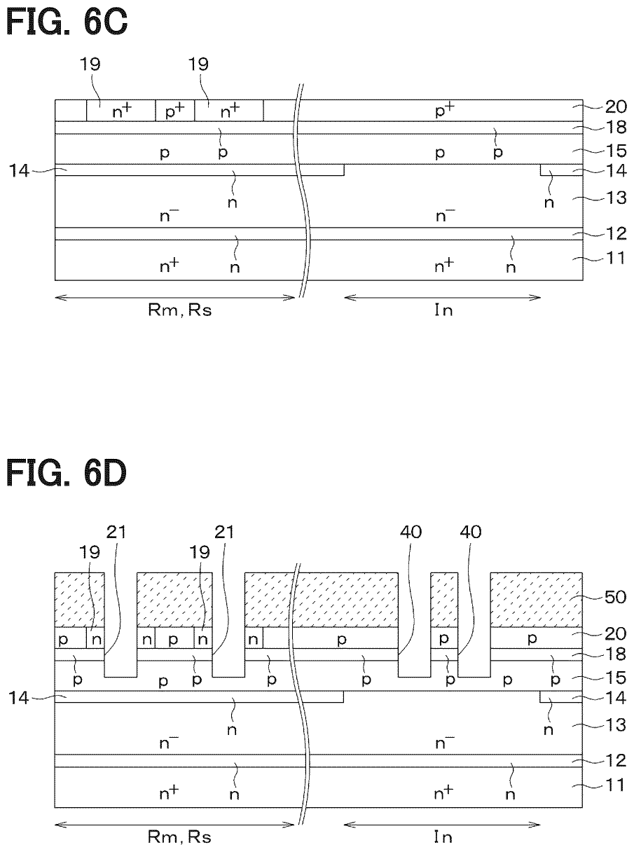

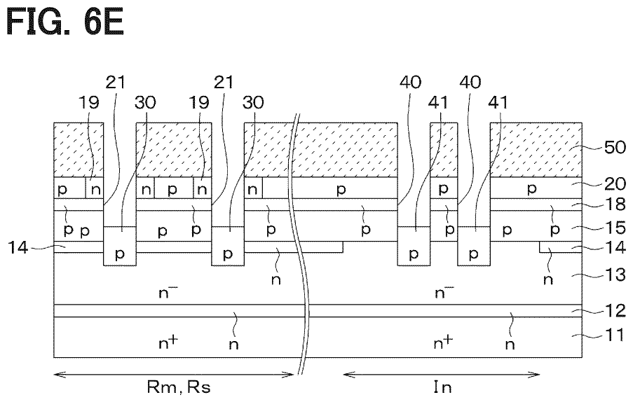

Next, a manufacturing method of the SiC semiconductor device according to the present embodiment will be described with reference to FIGS. 6A to 6E. In FIGS. 6A to 6E, a cross section in the main cell region Rm and the sense cell region Rs is shown on the left side, while a cross section in the element isolation region In is shown on the right side. Since the main cell region Rm and the sense cell region Rs have similar cross sections, they are described together.

First, as shown in FIG. 6A, after preparing the substrate 11, the buffer layer 12 and the low-concentration layer 13 are epitaxially grown on the front surface of the substrate 11. Then, after placing a mask (not shown) having openings at positions corresponding to the JFET layer 14, on the surface of the low-concentration layer 13, n-type impurity ions are implanted to form the JFET layer 14.

Subsequently, after again forming a mask (not shown) having openings at positions corresponding to the first deep layers 15, p-type impurity ions are implanted to form the first deep layers 15, as shown in FIG. 6B. In addition, after forming a mask (not shown) having openings at positions corresponding to the base layer 18, p-type impurity ions are implanted to form the base layer 18. Furthermore, using a mask having openings at positions corresponding to the contact region 20, p-type impurity ions are further implanted to form the contact region 20 on the base layer 18.

Thereafter, after forming a mask (not shown) having openings at positions corresponding to the source region 19, n-type impurity ions are implanted to form the source region 19, as shown in FIG. 6C. At this time, the contact region 20 has been formed extending to a region that will become the source region 19. However, by increasing the does of n-type impurity ions, it is possible to convert this region to n-type and thereby form the source region 19.

Next, as shown in FIG. 6D, after placing a mask 50 having openings at positions corresponding to the trenches 21 and the isolation trenches 40, the trenches 21 and the isolation trenches 40 are simultaneously formed by dry etching. Also, as shown in FIG. 6E, using the same mask 50, p-type impurity ions are implanted to form the second deep layers 30 at the bottom portions of the trenches 21, while simultaneously forming the isolation deep layers 41 at the bottom portions of the isolation trenches 40.

Thereafter, after forming the gate insulating film 22 by thermal oxidation or chemical vapor deposition (CVD), the gate electrode 23 and the isolation gate electrode 42 are simultaneously formed by depositing and patterning doped polysilicon. Then, processes of forming the interlayer insulating film 24, forming the upper electrode 25 and the gate wiring 26, forming the protective film 27, and forming the lower electrode 28 on the rear surface of the substrate 11 are performed using conventional methods. As a result, the SiC semiconductor device according to the present embodiment is completed.

According to the SiC semiconductor device according to the present embodiment, the isolation trenches 40 are formed in the element isolation region In, thereby separating the sections of the base layer 18 and the contact region 20 located adjacent to the main cell region Rm and the sections of the base layer 18 and the contact region 20 located adjacent to the sense cell region Rs. As a result, the electrical isolation between the sections of the base layer 18 and the contact region 20 located adjacent to the main cell region Rm and the sections of the base layer 18 and the contact region 20 located adjacent to the sense cell region Rs can be accurately achieved.

In addition, by providing the isolation deep layers 41, the rise of equipotential lines between the main cell region Rm and the sense cell region Rs can be suppressed, thereby ensuring breakdown voltage. Furthermore, since the plurality of isolation trenches 40 are formed, it is not necessary to widen each of the isolation trenches 40 as would be required if forming the isolation deep layers 41 at both ends of a single wide isolation trench 40. As a result, the adjacent isolation deep layers 41 can be prevented from being connected to each other.

That is, when simultaneously forming the trenches 21 and the isolation trenches 40, variations in the finished quality can occur if their widths differ. In the case where the isolation deep layers 41 are formed at both ends of a single wide isolation trench 40, the trench shapes become unstable. In addition, when forming the second deep layers 30 and the isolation deep layers 41, the ion implantation mask is placed on front surface 10a of the semiconductor substrate 10. However, within the isolation trench 40, a mask for separating the isolation deep layers 41 is arranged from the bottom surface of the isolation trench 40. Therefore, within the isolation trench 40, the mask height differs, resulting in variations in the finished quality of the isolation deep layers 41. Therefore, in the case where isolation deep layers 41 are formed at both ends of a single wide isolation trench 40, the isolation deep layers 41 may connect with each other, making it impossible to isolate the main cell region Rm and the sense cell region Rs.

In contrast, when providing a plurality of isolation trenches 40 as in the present embodiment, it is not necessary to make the width of each of the isolation trenches 40 wide, thereby enabling improved quality of the isolation trenches 40. Furthermore, since the isolation trench 40 located adjacent to the main cell region Em and the isolation trench 40 located adjacent to the sense cell region Rs are separated from each other by the spacing B2, the isolation deep layers 41 respectively disposed at the bottom portions of the isolation trenches 40 are also arranged separately from each other. As a result, source leakage due to short-circuiting between the isolation deep layer 41 located adjacent to the main cell region Rm and the isolation deep layer 41 located adjacent to the sense cell region Rs can be suppressed.

In addition, according to the manufacturing method of the SiC semiconductor device of the present embodiment, the following effects can also be obtained.

In the present embodiment, the isolation structure is formed by the isolation trenches 40. Therefore, the process of forming the trenches 21 and the process of forming the isolation trenches 40 can be unified, which simplifies the manufacturing process and reduces device manufacturing costs. In addition, in the element isolation region In, the isolation trenches 40 are formed so as to penetrate through the sections of the base layer 18 and contact region 20 located adjacent to the main cell region Rm, and the sections of the base layer 18 and contact region 20 located adjacent to the sense cell region Rs. Therefore, it is not necessary to form the base layer 18 and the contact region 20 by detailed patterning. In this respect as well, simplification of the manufacturing process can be achieved.

In addition, by using the mask employed during the formation of the isolation trenches 40, p-type impurity ions are implanted into the bottom portions of the isolation trenches 40 to form the isolation deep layers 41, thereby enabling the isolation deep layers 41 to be formed without mask misalignment. Therefore, the isolation trenches 40 and the isolation deep layers 41 can be formed without positional misalignment, eliminating variations in the finished product and making it possible to improve yield. In addition, since the process for forming the isolation deep layers 41 can be unified with the process for forming the second deep layer 30, the manufacturing process can be simplified and the device production cost can be reduced.

### OTHER EMBODIMENTS

Although the present disclosure has been described in accordance with the embodiments, it is understood that the present disclosure is not limited to such embodiments or structures. The present disclosure encompasses various modifications and variations within the scope of equivalents. Furthermore, various combinations and modes, and other combinations and modes including only one, more or fewer elements, fall within the spirit and scope of the present disclosure.

For example, in the above-described embodiment, the first deep layers 15 are formed up to the boundary position between the main cell region Rm and the sense cell region Rs, and are in contact with the isolation deep layers 41 formed in the element isolation region In. In other examples, the first deep layers 15 may extend to the bottom portions of the isolation trenches 40 and be partially overlapped with the isolation deep layers 41, or the first deep layers 15 may be separated from the isolation deep layers 41. However, if the distance between the first deep layers 15 and the isolation deep layers 41 is too long, there is a concern that the breakdown voltage may decrease due to the rise of equipotential lines. Therefore, it is preferable to set the distance to be equal to or less than the spacing B1 between the trenches 21 formed in the main cell region Rm.

In the above-described embodiment, the case where two isolation trenches 40 are formed is given as an example, but three or more isolation trenches 40 may also be formed. However, as the number of isolation trenches 40 increases, the area of the element isolation region In becomes larger, leading to an increase in chip area. Therefore, from the perspective of area efficiency, it is preferable that the number of the isolation trenches 40 be two.

Additionally, in the above-described embodiment, the bottom surfaces of the second deep layers 30 may be made shallower so that they are positioned within the JFET layer 14 and the first deep layers 15. In other words, the second deep layers 30 may be formed so as not to reach the low-concentration layer 13. According to this configuration, it becomes more difficult for a depletion layer to extend from the second deep layers 30, thereby enabling a reduction in on-resistance. When the second deep layers 30 and the isolation deep layers 41 are formed simultaneously, the bottom surfaces of the isolation deep layers 41 will also be formed shallow. However, the positions of the bottom surfaces of the second deep layers 30 and the isolation deep layers 41 may be adjusted based on breakdown voltage design.

Additionally, in the above-described embodiment, the JFET layer 14, the first deep layers 15, the base layer 18, and either the contact region 20 or the source region 19 are formed by ion implantation. Some or all of these components may be constituted by epitaxial layers formed by epitaxial growth.

Furthermore, in the element isolation region In, the source region 19 may be formed in the surface layer of the base layer 18, or the contact region 20 and the source region 19 may not be formed, in which case the gate insulating film 22 may be formed on the surface of the base layer 18.

Furthermore, in the above-described embodiment, the base layer 18 is formed on the surfaces of the JFET layer 14 and the first deep layers 15. However, an n-type current diffusion layer having a higher n-type impurity concentration than the low-concentration layer 13 may be formed between the base layer 18 and the surfaces of the JFET layer 14 and the first deep layers 15. In that case, in addition to the current diffusion layer, p-type connection layers may be formed on both sides of each of the trenches 21, and the base layer 18 may be formed over these current diffusion layers and connection layers. In this case, the structure becomes such that the first deep layers 15 and the base layer 18 are connected via the connection layers. Furthermore, the low-concentration layer 13, the JFET layer 14, and the current diffusion layers are connected, and these layers together constitute the drift layer 17. Even in the case of such a structure, the depths of the second deep layers 30 and the isolation deep layers 41 may be formed deeper than the first deep layers 15, or may be formed to a depth within the thickness of the first deep layers 15. Furthermore, in the above-described embodiment, the JFET layer 14 is also formed in the peripheral region 2. However, it is also acceptable that only the low-concentration layer 13 is present without forming the JFET layer 14.

Furthermore, in the above-described embodiment, the depth of the isolation trenches 40 may be different from that of the trenches 21. In addition, the isolation trenches 40 may be formed in a process separate from the process for forming the trenches 21. The isolation deep layers 41 may also be formed in a process separate from the process for forming the second deep layers 30.

In the above-described embodiment, as the semiconductor device provided in the cell region 1, a vertical MOSFET having a trench gate structure of the n-channel type has been described as an example, in which the first conductivity type is n-type and the second conductivity type is p-type. However, this is merely an example, and, for instance, a vertical MOSFET having a trench-gate structure of the p-channel type, in which the conductivity types of the respective components are reversed from those of the n-channel type, may also be used. Furthermore, a vertical IGBT having a similar structure may be provided instead of the vertical MOSFET. In the case of an IGBT, except for changing the conductivity type of the substrate 11 from n-type to p-type in the above-described embodiment, the configuration is the same as the vertical MOSFET described in the above-described embodiment.

It should be noted that, when indicating crystal orientation, a bar (-) should originally be placed above the desired numeral. However, due to limitations in representation arising from electronic filing, in the present specification, a bar is placed before the desired numeral.

What is claimed is:

1. A silicon carbide semiconductor device having a cell region that includes a main cell region, a sense cell region, and an element isolation region electrically separating the main cell region and the sense cell region, the silicon carbide semiconductor device comprising:
a substrate made of silicon carbide of a first conductivity type or a second conductivity type; and
a first impurity region of the first conductivity type having a lower impurity concentration than the substrate and disposed above a front surface of the substrate, wherein
both the main cell region and the sense cell region include
a junction field effect transistor (JFET) layer made of silicon carbide of the first conductivity type, disposed in a surface layer of the first impurity region, and having a higher impurity concentration than the first impurity region,
a deep layer made of silicon carbide of the second conductivity type, disposed in the surface layer of the first impurity region, and arranged alternately with the JFET layer in a planar direction of the substrate,
a base layer made of silicon carbide of the second conductivity type, and disposed above the JFET layer and the deep layer,
a trench gate structure including a plurality of gate trenches arranged in parallel along one direction as a longitudinal direction and extending deeper than the base layer, a gate insulating film disposed on inner wall surfaces of the plurality of gate trenches, and a gate electrode disposed on the gate insulating film within the plurality of gate trenches,
a second impurity region made of silicon carbide of the first conductivity type, disposed in a surface layer of the base layer in contact with the trench gate structure, and having a higher impurity concentration than the first impurity region,
a first electrode separately disposed in the main cell region and the sense cell region, the first electrode disposed in the main cell region electrically connected to the second impurity region and the base layer disposed in the main cell region, and the first electrode disposed in the sense cell region electrically connected to the second impurity region and the base layer disposed in the sense cell region, and
a second electrode disposed on a rear surface of the substrate and electrically connected to the substrate,
the element isolation region includes
a plurality of isolation trenches disposed between the main cell region and the sense cell region, and extending deeper than the base layer to separate the base layer into a section adjacent to the main cell region and a section adjacent to the sense cell region, and
a plurality of isolation deep layers of the second conductivity type respectively disposed at bottom portions of the plurality of isolation trenches in contact with bottom surfaces of the plurality of isolation trenches,
the deep layer is further disposed in the surface layer of the first impurity region disposed in the element isolation region, and
the JFET layer is not disposed in the element isolation region.

2. The silicon carbide semiconductor device according to claim 1, wherein
the deep layer is a first deep layer, and
the trench gate structure further includes a plurality of second deep layers of the second conductivity type respectively disposed at bottom portions of the plurality of gate trenches in contact with bottom surfaces of the plurality of gate trenches.

3. The silicon carbide semiconductor device according to claim 2, wherein
a spacing between the plurality of isolation trenches is smaller than a spacing between the plurality of gate trenches.

4. The silicon carbide semiconductor device according to claim 3, wherein
each the plurality of isolation trenches has a width equal to a width of each of the plurality of the gate trenches.

5. The silicon carbide semiconductor device according to claim 1, wherein
the sense cell region is surrounded by the plurality of isolation trenches.
